(19) United States
(12) Patent Application Publication
(10) Pub. No.: US 2012/0298412 A1
(43) Pub. Date: Nov. 29, 2012

(54) PRINTED CIRCUIT BOARD AND METHOD OF MANUFACTURING THE SAME

(75) Inventors: Kyung Don Mun, Gyunggi-do (KR); Min Jung Cho, Gyunggi-do (KR); Sun Uk Hwang, Seoul (KR)

(73) Assignee: SAMSUNG ELECTRO-MECHANICS CO., LTD., Gyunggi-do (KR)

(21) Appl. No.: 13/204,425

(22) Filed: Aug. 5, 2011

(30) Foreign Application Priority Data
May 25, 2011 (KR) 1020110049753

(51) Int. Cl. H05K 1/11; H05K 3/42

(52) U.S. Cl. 174/266; 29/852

(57) ABSTRACT

Disclosed herein are a printed circuit board and a method of manufacturing the same. The method of manufacturing a printed circuit board includes: preparing a base substrate having first circuit layers formed on one surface or both surfaces thereof; forming a plating resist having openings for a first via layer on the base substrate; forming first via layers in the openings for a first via layer; forming insulating layers having outer metal layers on the base substrate having the first via layers formed thereon; forming openings for a second via layer over the first via layer on the insulating layers and the outer metal layers; and completing multi-layer vias by forming second via layers in the openings.

### CROSS REFERENCE TO RELATED APPLICATION

This application claims the benefit of Korean Patent Application No. 10-2011-0049753, filed on May 25, 2011, entitled “Printed Circuit Board and Method of Manufacturing the Same”, which is hereby incorporated by reference in its entirety into this application.

### BACKGROUND OF THE INVENTION

1. Technical Field

The present invention relates to a printed circuit board and a method of manufacturing the same.

2. Description of the Related Art

With the development of electronic industries, the number of electronic components has increased and use range and function of portable electronic equipment products have recently diversified. There has also been a continuing effort to ensure quality of a product, reduction in costs, and high density thereof, in order to ensure that the product retains a competitive edge on the market.

Meanwhile, at least 4-layer flip chip chip scale package (FCCSP) needs a full stack via-shaped via structure and a fine pitch circuit.

Therefore, an operator in the pertinent technical field is conducting a research on a method capable of simplifying a processing procedure of a printed circuit board as well as a via structure by which a fine pitch can be implemented.

### SUMMARY OF THE INVENTION

The present invention has been made in an effort to provide a printed circuit board and a method of manufacturing the same capable of reducing the number of laser processes at the time of processing a via hole for forming a via and a processing procedure thereof by configuring a single via in a multi-layer.

According to an exemplary embodiment of the present invention, there is provided a method of manufacturing a printed circuit board, including: preparing a base substrate having first circuit layers formed on one surface or both surfaces thereof; forming a plating resist having openings for a first via layer on the base substrate; forming first via layers in the openings for a first via layer; forming insulating layers having outer metal layers on the base substrate having the first via layers formed thereon; forming openings for a second via layer over the first via layer on the insulating layers and the outer metal layers; and completing multi-layer vias by forming second via layers in the openings.

The preparing of the base substrate may include: forming seed layers on the base substrate; forming a plating resist having openings for forming a first circuit on the seed layers; and forming the first circuit layers in the openings for forming a first circuit.

The forming of the seed layers may include forming the seed layers by electroless plating or electroplating.

The method may further include removing the plating resist, after the forming of the first via layers and before the forming of the insulating layers having outer metal layers on the base substrate.

The removing of the plating resist may further include removing the exposed seed layers, the base substrate further including seed layers formed thereon.

The forming of the plating resist may include: forming a plating resist on the base substrate; and processing the openings for a first via layer so as to expose the first circuit layers.

The plating resist may be formed of a dry film.

The forming of the first via layers may include forming the first via layers in the openings for a first via layer by pattern plating.

The forming of the openings may include forming the openings using any one of CO₂ laser or YAG laser.

The completing of the multi-layer vias may include: forming the seed layers on the outer metal layers and the openings for forming a second via layer; and forming second via layers on the seed layers by plating.

The method may further include forming second circuit layers on the outer metal layers and the metal layers for a circuit, after the completing of the multi-layer vias, wherein the completing of the multi-layer vias by forming second via layers in the openings includes forming metal layers for a circuit on the outer metal layers when forming the second via layers.

The base substrate may have inner layer through vias formed therein.

The first via layer may have a thickness larger than that of the second via layer.

The second via layer may have a tapered shape in which a diameter thereof is increasing in a direction towards an outer layer of the substrate.

According to another exemplary embodiment of the present invention, there is provided a printed circuit board, including: a base substrate having first circuit layers formed on one surface or both surfaces thereof; insulating layers formed on the base substrate and having openings for a multi-layer via exposing the first circuit layers; and multi-layer via including first via layers formed in the openings for a multi-layer via and second via layers formed on the first via layers.

The base substrate may have inner layer through vias formed therein.

The first via layer may have a thickness larger than that of the second via layer.

The second via layer may have a tapered shape in which a diameter thereof is increasing in a direction towards an outer layer of the substrate.

The multi-layer via may be formed by plating.

### BRIEF DESCRIPTION OF THE DRAWINGS

FIG. 1 is a diagram showing a configuration of a printed circuit board according to the present invention; and

FIGS. 2 to 9 are schematic views sequentially showing the process of manufacturing the printed circuit board of FIG. 1.

### DESCRIPTION OF THE PREFERRED EMBODIMENTS

Various features and advantages of the present invention will be more obvious from the following description with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, a detailed description thereof will be omitted. In the description, the terms “first”, “second”, and so on are used to distinguish one element from another element, and the elements are not defined by the above terms.

Hereinafter, preferred embodiments of the present invention will be described in detail with reference to the accompanying drawings.

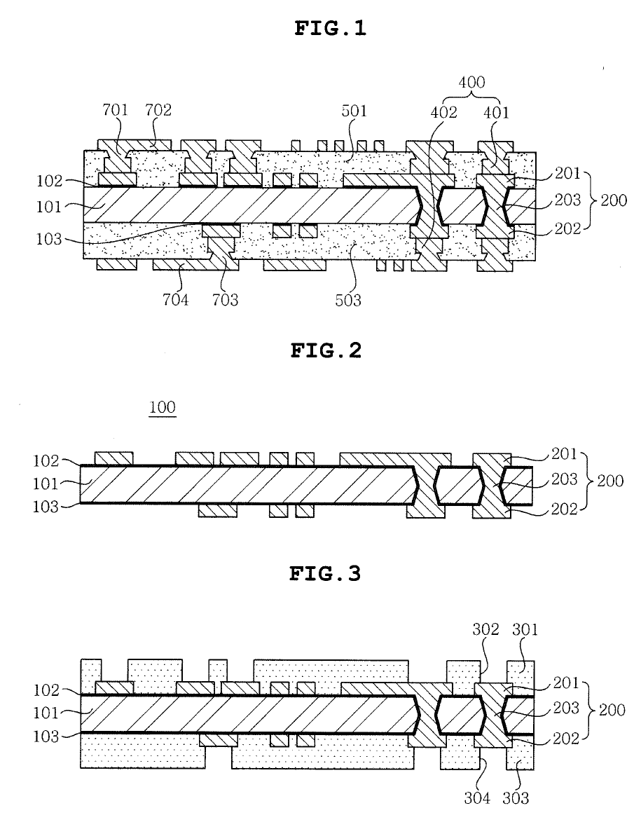

FIGS. 1 to 9 show a case in which a first circuit layer is formed on both surfaces of a base substrate by way of example; however, they are not limited thereto but may also show a case in which the first circuit layer is formed on any one of an upper portion and a lower portion thereof to be described below.

Printed Circuit Board

FIG. 1 is a diagram showing a configuration of a printed circuit board according to the present invention.

Referring to FIG. 1, a printed circuit board 100 is configured to include a base substrate 101 having first circuit layers 200, 201, and 202 formed on one surface or both surfaces thereof, insulating layers 501 and 503 formed on the base substrate 101 and having openings for a multi-layer via (not shown) exposing the first circuit layers 201 and 202, and a multi-layer via including first via layers 400, 401, and 402 formed in the openings for a multi-layer via and second via layers 701 and 703 formed on the first via layers 400, 401, and 402 (hereinafter, referred to as 400).

In the present invention, the multi-layer via has a structure where the first via layer 400 and the second via layers 701 and 703 are coupled to each other, which forms, for example, a multi-layer tower shape, in which a top portion of the outermost layer thereof may have a tapered shape; however, the multi-layer via is not limited thereto.

In other words, the multi-layer via will be defined as a via that one via is configured of a multi-layer. In this case, the shapes of the vias in each layer may be different from or identical to each other.

In addition, a resin insulating layer may be used as the insulating layers 501 and 503. For example, as the resin insulating layer, a thermosetting resin such as an epoxy resin, a thermoplastic resin such as polyimide, or a resin that a reinforcement such as a glass fiber or an inorganic filler is impregnated therein, for example, a prepreg, a thermosetting resin and/or a photocurable resin, and the like, may be used; however, it is not specifically limited thereto.

An inner layer through via 203 may be formed in the base substrate 101.

As shown in FIG. 2, the inner layer through via 203 is connected to the first circuit layers 201 and 202 to thereby be electrically conducted.

The printed circuit board 100 may further include the second circuit layers 702 and 704 on the insulating layers 501 and 503. In this case, the second circuit layers 702 and 704 are formed on the top portions of the multi-layer vias and electrically connected to the multi-layer vias.

Any one used as a conductive metal for a circuit in a circuit substrate field may be applied to the first circuit layers 201 and 202 and the second circuit layers 702 and 704 without limitation; however, copper is generally used in the printed circuit board.

The multi-layer via may be formed by plating.

The plating disclosed in the present invention is performed by electrolytic plating. Even though a fill plating process to which exclusive fill plating chemicals are applied is not performed, effects of the fill plating that completely fills via holes may be expected through a plating process to form a plating layer only on inner walls of the via holes.

The reason is that since the multi-via of the present invention has a multi-layer via structure in which the first via layer 400 is formed and then the second via layers 701 and 703 are formed on the first via layer 400, the via holes for forming the second via layers 701 and 703 have a depth lower than that of a single-layer via hole according to the prior art. The detailed description thereof will be described below.

The first via layer 400 has a thickness larger than that of the second via layers 701 and 703.

The second via layers 701 and 703 may have a tapered shape in which diameters thereof are increasing in a direction towards an outer layer of the substrate.

As described above, the first via layer 400 has a larger volume as well as a larger thickness than those of the second via layers 701 and 703, thereby making it possible to have improved reliability with respect to the vias.

Method of Manufacturing Printed Circuit Board

FIGS. 2 to 9 are schematic views sequentially showing the process of manufacturing the printed circuit board of FIG. 1.

First referring to FIG. 2, a base substrate 101 having first circuit layers 200, 201, and 202 (hereinafter, referred to as 200) formed on one surface or both surfaces thereof is prepared.

In more detail, the preparing of the base substrate 101 may include forming seed layers 102 and 103 on the base substrate 101, forming a plating resist (not shown) having openings for forming a first circuit on the seed layers 102 and 103, and forming first circuit layers 200 in the openings for forming a first circuit.

In this case, the seed layers 102 and 103 may be formed by electroless plating or electroplating.

In addition, the base substrate 101 may include inner layer through vias 203.

Referring to FIG. 3, plating resists 301 and 303 having openings for a first via layer 302 and 304 are formed on the base substrate 101.

In more detail, the forming of the plating resists 301 and 303 may include forming the plating resists 301 and 303 on the base substrate 101, and processing openings for a first via layer 302 and 304 so as to expose the first circuit layer 200.

As the plating resists 301 and 303, a dry film or a photosensitive resist such as a positive liquid photo resist (P-LPR) may be used. After the photosensitive resist is applied to the exposed seed layers 102 and 103 and the first circuit layer 200, a portion corresponding to a region for forming the first via layer is exposed to ultraviolet rays and the exposed portion is removed using a developer, thereby forming openings.

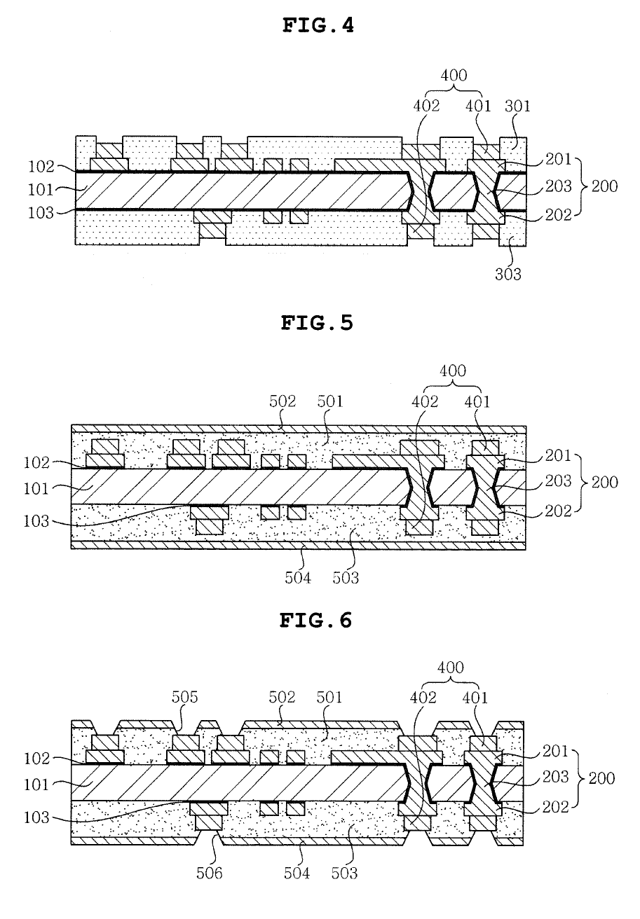

Referring to FIG. 4, first via layers 400, 401, and 402 (hereinafter, referred to as 400) are formed in the openings for a first via layer 302 and 304 by pattern plating.

Then, the plating resists 301 and 303 are removed.

When the plating resists 301 and 303 are removed, the exposed seed layers 102 and 103 are simultaneously removed.

In this case, the plating resists 301 and 303 are removed using a stripper such as, sodium hydroxide (NaOH), potassium hydroxide (KOH), or the like, and the seed layers 102 and 103 are removed by quick etching, flash etching, or the like.

In the present invention, the seed layers 102 and 103 formed on the base substrate 101 are not removed before the first circuit layer 200 is formed. After the plating resists 301 and 303 are formed and the first via layer 400 is formed, the seed layers 102 and 103 are removed simultaneously with removing of the plating resists 301 and 303.

As a result, a separate process of processing the seed layers right before the forming of the plating resists 301 and 303 is removed, thereby making it possible to simplify a processing procedure.

The first via layer 400 may also be formed in the openings for a first via layer by pattern plating.

Referring to FIG. 5, insulating layers 501 and 503 having outer metal layers 502 and 504 are formed on the base substrate 101 having the first via layer 400 formed thereon.

Here, any one used as a conductive metal for a circuit in a circuit substrate field may be applied to the outer metal layer without limitation; however, copper is generally used in the printed circuit board

A copper clad laminate (CCL) in which a copper foil is laminated on one surface of an insulating layer may be used as the outer metal layers 502 and 504 and the insulating layers 501 and 503.

Referring to FIG. 6, openings 505 and 506 for forming a second via layer on the first via layer 400 are formed in the insulating layers 501 and 503 and the outer metal layers 502 and 504.

In this case, the openings 505 and 506 may be processed using any one of CO₂ laser or YAG laser.

Here, the depth of the openings 505 and 506 is lower than that of the via holes for a single via according to the prior art, thereby making it possible to reduce the number of laser processes as compared to the prior art.

Thereafter, although not shown, a desmear process removing smear that may occur at the time of processing via holes may be performed.

In the present invention, the depth of the via hole (based on a thickness direction of the substrate) is lower than that of the via hole of the prior art, such that the number of shots at the time of laser processing is significantly reduced compared to the prior art. As a result, the smear generation amount is also reduced, thereby making it also possible to simplify the desmear process.

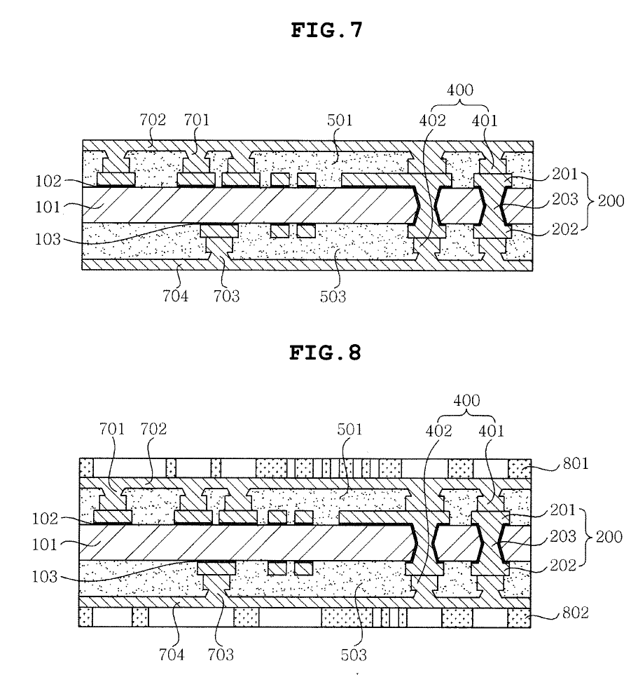

Referring to FIG. 7, second via layers 701 and 703 are formed in the openings 505 and 506 to thereby complete a multi-layer via.

In more detail, the completing of the multi-layer via may include forming seed layers (not shown) on the outer metal layers 502 and 504 by including the openings 505 and 506 for the second via layers 701 and 703, and forming the second via layers 701 and 703 on the seed layers by plating.

Here, when the forming of the second via layers 701 and 703, the plating is performed by electrolytic plating. Even though a fill plating process to which exclusive fill plating chemicals are applied is not performed, effects of the fill plating may be expected through a plating process to form a plating layer only on inner walls of the via holes.

The reason is that since the multi-via of the present invention has a multi-layer via structure in which the first via layer 400 is formed and then the second via layers 701 and 703 are formed on the first via layer 400, the via holes (openings 505 and 506) for forming the second via layers 701 and 703 have a depth lower than that of a single-layer via hole according to the prior art.

Therefore, at the forming of the openings 505 and 506 for forming the second via layers 701 and 703, the height of the openings is to be processed so that the openings 505 and 506 may be filled by plating.

Here, when forming the second via layers 701 and 703, the via may be formed by performing plating inside the via holes, even though a fill plating process to which expensive exclusive fill plating chemicals are applied is not performed, thereby making it possible to reduce a manufacturing cost and a manufacturing process.

In more detail, expensive exclusive fill plating chemicals should be applied in order to perform fill plating; however, the present invention forms the first via layer in a pad shape at the time of forming a via and then performs laser processing on the via holes forming a second via layer over the first via layer, such that the depth of the via holes may be lower than that of the via holes for the fill plating according to the prior art, thereby lowering the manufacturing cost of the substrate.

In addition, a fine pitch of the outer layer circuit may be implemented due to the low plating thickness of the second via layers 701 and 703.

For example, the via hole according to the prior art has a large depth of about 40 μm or more in a thickness direction of the substrate to allow a large difference between a diameter of an outer layer upper surface of the via hole and that of an inner lower surface thereof in view of the laser processing characteristics when the via hole is processed by laser. However, the via hole according to the present invention has a depth of 5 to 15 μm to allow a small difference between a diameter of an outer layer upper surface of the via hole and that of an inner lower surface thereof, thereby making it possible to expect a fine pitch of a circuit.

Meanwhile, at the forming of the second via layers 701 and 703, a metal layer for a circuit for forming second circuit layers 702 and 704 is also formed on the outer metal layers 502 and 504. In other words, at the time of plating for forming the second via layers 701 and 703, the metal layer for a circuit is also formed on the outer metal layers 502 and 504.

Here, the metal layer for a circuit is subsequently processed together with the outer metal layers 502 and 504 to be formed as the second circuit layers 702 and 704, which are an outer layer circuit.

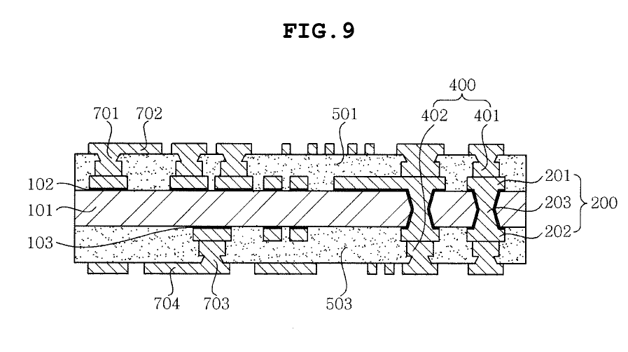

Referring to FIGS. 8 and 9, the second circuit layers 702 and 704 are formed on the outer metal layers 502 and 504 and the metal layer for a circuit.

In this case, the second circuit layers may be formed by a tenting scheme of forming etching resist patterns 801 and 802 on the metal layer for a circuit and removing portions on which the etching resist patterns are not formed using an etchant to allow the remaining portion to be a circuit pattern, as shown in FIGS. 8 and 9; however, they are not limited thereto but may also be formed by a semi-additive scheme and an additive scheme.

Here, any one used as a conductive metal for a circuit in a circuit substrate field may be applied to the metal layer for a circuit without limitation; however, copper is generally used in the printed circuit board.

Meanwhile, in the present invention, after the metal layers for a circuit are formed on the outer metal layers 502 and 504, the second circuit layers 702 and 704, which are an outer layer circuit layer, are formed using the tenting scheme, such that there is no limitation in the thickness of the outer metal layers 502 and 504, thereby making it possible to improve freedom in design of a substrate.

Preferably, the first via layer 400 has a thickness larger than that of the second via layers 701 and 703.

The second via layers 701 and 703 may have a tapered shape in which diameters thereof are increasing in a direction towards an outer layer of the substrate.

On the other hand, the second via layers 701 and 703 may also be formed using pattern plating of a plurality of plating schemes. When the second via layers 701 and 703 are formed using pattern plating, the plating resist patterned after the forming of the openings 505 and 506 for forming the second via layers as shown in FIG. 6 are formed on the outer metal layers 502 and 504 and then the plating process is performed thereon, thereby forming the second circuit layers 702 and 704 shown in FIG. 9.

With the printed circuit board and the method of manufacturing the same according to the present invention, the first via layers are formed before performing a laser processing for forming the via holes, such that the number of laser shots at the time of laser processing can be reduced, thereby making it possible to reduce the processing procedure and the processing costs.

In the present invention, as the depth of the via hole formed by laser processing becomes lower, the amount of smear is reduced and thus the number of desmear processes is also reduced, thereby making it possible to simplify the entire processing procedure.

In the present invention, as the depth of the via hole formed by laser processing becomes lower, the via hole may be formed by a plating process other than a fill plating, such that expensive chemicals used in performing the fill plating are not used, thereby making it possible to reduce manufacturing costs.

In the present invention, the multi-layer via of which a lower portion has a larger volume than an upper portion thereof is used, thereby making it possible to improve reliability of the via.

Although the preferred embodiments of the present invention have been disclosed for illustrative purposes, they are for specifically explaining the present invention and thus a printed circuit board and a method of manufacturing the same according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A method of manufacturing a printed circuit board, the method comprising:
preparing a base substrate having first circuit layers formed on one surface or both surfaces thereof;
forming a plating resist having openings for a first via layer on the base substrate;
forming first via layers in the openings for a first via layer;
forming insulating layers having outer metal layers on the base substrate having the first via layers formed thereon;
forming openings for a second via layer over the first via layer on the insulating layers and the outer metal layers; and
completing multi-layer vias by forming second via layers in the openings.

2. The method as set forth in claim 1, wherein the preparing of the base substrate includes:
forming seed layers on the base substrate;
forming a plating resist having openings for forming a first circuit on the seed layers; and
forming the first circuit layers in the openings for forming a first circuit.

3. The method as set forth in claim 2, wherein the forming of the seed layers includes forming the seed layers by electroless plating or electroplating.

4. The method as set forth in claim 1, further comprising removing the plating resist, after the forming of the first via layers and before the forming of the insulating layers having outer metal layers on the base substrate.

5. The method as set forth in claim 4, wherein the removing of the plating resist further includes removing the exposed seed layers, the base substrate further including seed layers formed thereon.

6. The method as set forth in claim 1, wherein the forming of the plating resist includes:
forming a plating resist on the base substrate; and
processing the openings for a first via layer so as to expose the first circuit layers.

7. The method as set forth in claim 1, wherein the plating resist is formed of a dry film.

8. The method as set forth in claim 1, wherein the forming of the first via layers includes forming the first via layers in the openings for a first via layer by pattern plating.

9. The method as set forth in claim 1, wherein the forming of the openings includes forming the openings using any one of CO₂ laser or YAG laser.

10. The method as set forth in claim 1, wherein the completing of the multi-layer vias includes:
forming the seed layers on the outer metal layers and the openings for forming a second via layer; and
forming second via layers on the seed layers by plating.

11. The method as set forth in claim 1, further comprising forming second circuit layers on the outer metal layers and the metal layers for a circuit, after the completing of the multi-layer vias,
wherein the completing of the multi-layer vias by forming second via layers in the openings includes forming metal layers for a circuit on the outer metal layers when forming the second via layers.

12. The method as set forth in claim 1, wherein the base substrate has inner layer through vias formed therein.

13. The method as set forth in claim 1, wherein the first via layer has a thickness larger than that of the second via layer.

14. The method as set forth in claim 1, wherein the second via layer has a tapered shape in which a diameter thereof is increasing in a direction towards an outer layer of the substrate.

15. A printed circuit board, comprising:
a base substrate having first circuit layers formed on one surface or both surfaces thereof;
insulating layers formed on the base substrate and having openings for a multi-layer via exposing the first circuit layers; and
multi-layer via including first via layers formed in the openings for a multi-layer via and second via layers formed on the first via layers.

16. The printed circuit board as set forth in claim 15, wherein the base substrate has inner layer through vias formed therein.

17. The printed circuit board as set forth in claim 15, wherein the first via layer has a thickness larger than that of the second via layer.

18. The printed circuit board as set forth in claim 15, wherein the second via layer has a tapered shape in which a diameter thereof is increasing in a direction towards an outer layer of the substrate.

19. The printed circuit board as set forth in claim 15, wherein the multi-layer via is formed by plating.
